(19) United States
(12) Patent Application Publication
(10) Pub. No.: US 2004/0136546 A1
(43) Pub. Date: Jul. 15, 2004

(54) Tone converter and tone converting method of the same

(76) Inventor: Hyen-O Oh, Seoul (KR)

Correspondence Address: BIRCH STEWART KOLASCH & BIRCH, PO BOX 747, FALLS CHURCH, VA, 22040-0747, US

(21) Appl. No.: 10/745,974

(22) Filed: Dec. 29, 2003

(30) Foreign Application Priority Data
Dec. 26, 2002 (KR) P2002-84455

(51) Int. Cl. H04B 3/20; H03G 5/00

(52) U.S. Cl. 381/101; 381/66

(57) ABSTRACT

Disclosed are a tone converter and a tone converting method employed in a process of playing music, voice, and an audio signal. The tone converter includes at least one delayer for generating an echo pulse by delaying an input audio signal for a predetermined time, a multiplier for multiplying a time delay value of the echo pulse outputted from a corresponding delayer by a gain value, and an adder for adding an echo signal outputted from the multiplier to the input audio signal so as to output a tone converted audio signal.

### CROSS-REFERENCE TO RELATED APPLICATIONS

This application claims the benefit of Korean Application No. P2002-84455, filed on Dec. 26, 2002, which is hereby incorporated by reference as if fully set forth herein.

### BACKGROUND OF THE INVENTION

1. Field of the Invention

The present invention relates to a tone converter and a tone converting method, and more particularly, to the tone converter and the tone converting method in a process of playing music, voice, and audio.

2. Discussion of the Related Art

In general, tone convert is controlling sound quality and a notion of space by changing of audio signal frequency and a time reply characteristic.

Tone convert is commonly used in an audio amp for replaying broadcasting or audio signals and a microphone amp for amplifying a voice signal.

In general, a conventional apparatus of tone convert is assembled with a few filters. Accordingly, the conventional tone converter not only needs relatively more operating amount but also had a problem of signal convert resulted from a replay of an incongruent filter.

### SUMMARY OF THE INVENTION

Accordingly, the present invention is directed to a tone converter and a tone converting method that substantially obviates one or more problems due to limitations and disadvantages of the related art.

An object of the present invention is to provide a tone converter and a tone converting method for easily and effectively converting a tone by using an echo or reverberation.

Another object of the present invention is to provide a tone converter and a tone converting method with a simple structure and a tone converting method of the same.

Another object of the present invention is to provide a tone converter and a tone converting method for enhancing sound quality and converting the tone into various tones.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, the tone converter includes at least one delayer for generating echo pulses by delaying an input audio signal for a predetermined time, a multiplier for multiplying a delayed time value of echo pulse outputted from a correspondent delayer by a gain value of echo pulse, and an adder for outputting a tone-converted audio signal by adding an echo signal outputted from the multiplier and an input audio signal.

A plurality of delayers and multipliers are comprised, and each of the delayer is correspondent to each of the multiplier. Number of the delayer and the multiplier is determined according to number of the echo pulse. The delayer is a memory buffer for storing an audio signal in a size of a distance between the echo pulse and the input audio signal pulse.

A tone converter includes a first delayer for generating a first echo pulse by delaying an input audio signal for a predetermined time; a first multiplier for multiplying a time delay value of the first echo pulse outputted from the first delayer by a gain value of the first echo pulse; a second delayer for generating a second echo pulse by delaying an audio signal outputted from the first delayer for a predetermined time; a second multiplier for multiplying a time delay value of the first echo pulse outputted from the first delayer by a gain value of the first echo pulse; and an adder for adding an echo signal outputted from the multiplier to the input audio signal so as to output tone converted audio signal.

The first multiplier and the second multiplier are arranged to be correspondent to the first delayer and the second delayer, relatively. The first delayer is a memory buffer for storing the audio signal in a size between the first echo pulse and the input audio signal pulse and the second delayer is a memory buffer for storing the audio signal in a size between the second echo pulse and the first echo pulse.

In another aspect of the present invention, a tone converter includes at least one delayer and multiplier, and an adder, the method comprising the steps of inputting the audio signal; delaying the input audio signal for a predetermined time so as to generate the echo pulse; multiplying a time delay value of the echo pulse by a gain value of the echo pulse; and adding the multiplied echo signal and the input audio signal so as to output a tone converted audio signal.

In this case, a repeated period of a frequency response of the echo signal is an inverse number of the time delay value of the echo pulse. The tone converted audio signal is determined by a following mathematical formula.

$$y ( n ) = x ( n ) + {\sum }^{Number of Echo Pulses} {g}_{i} x ( n - di ) \qquad [ Mathematical Formula ]$$

Wherein, x(n): an input audio signal, y(n): an output audio signal, gᵢ: gain value (0-1) of i times echo pulse, and di: time delay value of i times echo pulse.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIG. 1 illustrates a diagram showing impulse response for inserting echo pulse.

FIGS. 2A and 2B illustrate diagrams showing impulse response of an echo signal and frequency response of the impulse response when there is one positive echo pulse.

FIG. 3 illustrates a diagram showing a critical band rate of the frequency response of FIG. 2.

FIGS. 4A and 4B illustrate a diagram showing impulse response of an echo signal and frequency response of the impulse response when there is one negative echo pulse.

FIGS. 5A and 5B illustrate a diagram showing impulse response of an echo signal and frequency response of the impulse response when there are two positive echo pulses.

FIGS. 6A and 6B illustrate a diagram showing impulse response of an echo signal and frequency response of the impulse response when there is one positive echo pulse and one negative echo pulse.

FIGS. 7A and 7B illustrate a diagram showing impulse response of an echo signal and frequency response of the impulse response when there are four positive echo pulses.

FIGS. 8A and 8B illustrate a diagram showing impulse response of an echo signal and frequency response of the impulse response when there are two positive echo pulses and two negative echo pulses.

FIGS. 9A and 9B illustrate a diagram showing a change of frequency response according to a distance between and a size of an original signal and an echo signal.

FIGS. 10 illustrates a tone converter in accordance with the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

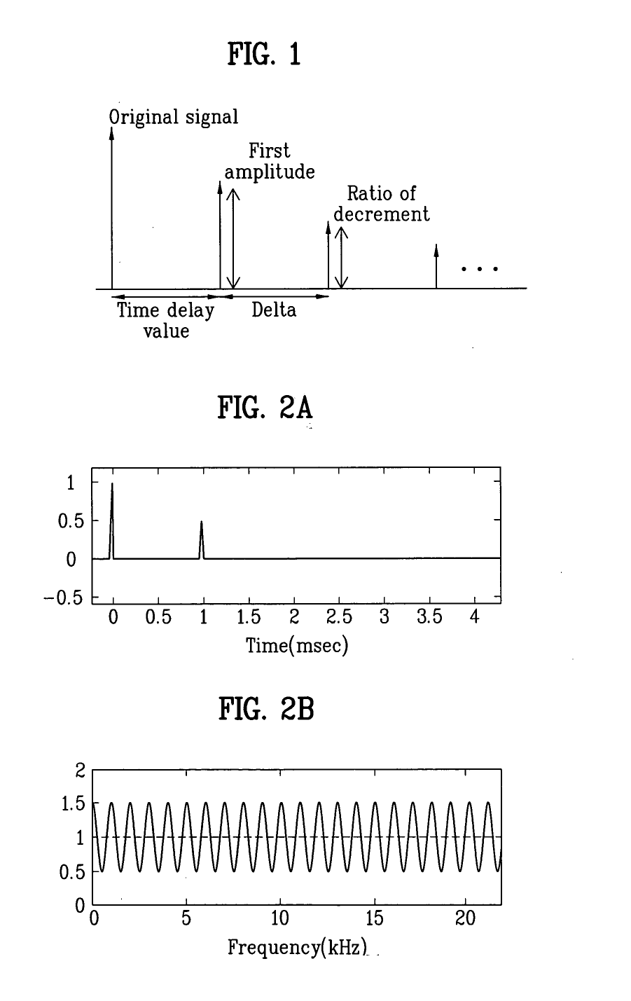

First, principle of the present invention is as follows. An echo means adding a delayed original signal to an original signal a plurality of times. The echo is represented by inserting into a function of an impulse response as that of FIG. 1.

In this case, an audio signal with the echo has a characteristic that is perceived different by human ear according to a delayed time value of the echo.

An original signal known as the echo is heard by ear again when a time delay is long enough (over 50 ms) and only coloration changing the signal tone is presented when time delay is short.

An example is that tone is changed according to a room size, a structure, and a wall material when listening to music using a speaker in a room.

In other words, a tone change is generated when an echo with a short time delay is inserted into an original signal. In this case, different tones are presented by controlling the number of impulse response, and a length and size of time delay.

FIGS. 2A and 2B illustrate diagrams showing impulse response of an echo signal and frequency response of the impulse response when there is one positive echo pulse.

As illustrated in FIGS. 2A and 2B, the tone of the original signal is converted by inserting the response signal into the original signal which is the audio signal.

In general, a human ear is capable of perceiving nonlinear frequency having a higher resolving power for low frequency than for high frequency. This can be well described by the critical band having a similar characteristic to a log function.

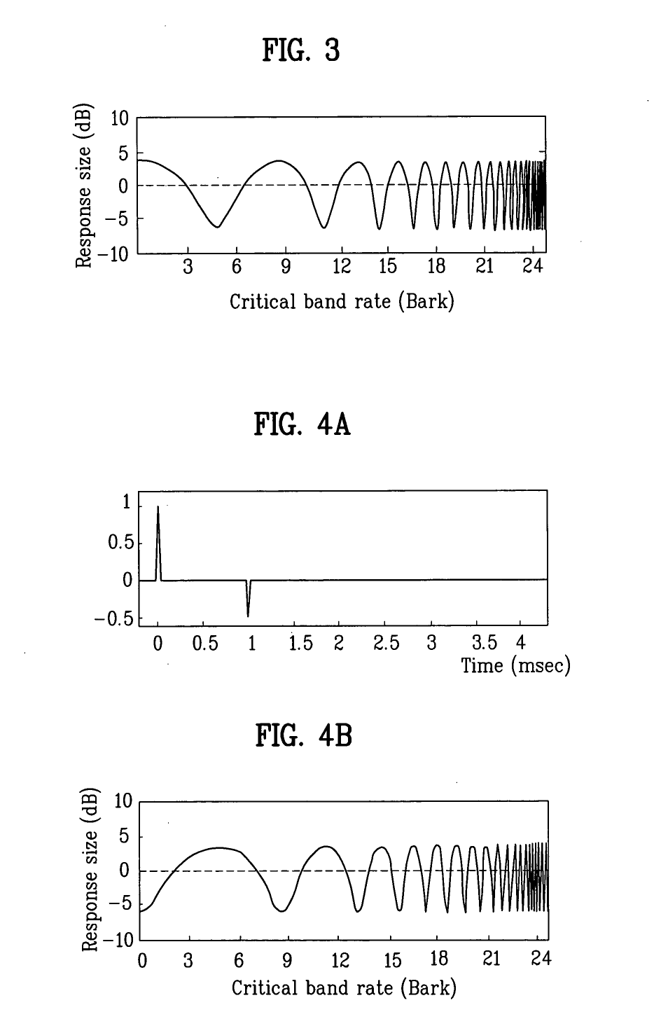

FIG. 3 illustrates a diagram showing a critical band rate of the frequency response of FIG. 2. As illustrated in FIG. 3, a change rate of frequency response by the echo is very slow in a high critical band and very fast in a low critical band.

In this case, the human ear is not able to distinguish a response change in a high critical band because of a limit of the frequency resolving power. Therefore, the response characteristic in a low critical band is an important element of a whole tone.

In a case of a general audio signal, most of energy exists at less than 10 bark which is correspondent to about 1 kHz and thus the influence of the response characteristic in the low frequency band influencing the whole tone is larger.

As illustrated in FIG. 3, the frequency component corresponding to about 0-3 bark is amplified and the frequency component corresponding to about 3-6 bark is decreased when there is one echo pulse and the time delay value of the echo pulse is about 1 msec.

When the echo pulse is inserted into the audio signal, a sound quality change is occurred. A low tone is amplified and the tone of the audio signal becomes glamorous giving a warm feeling.

In this case, p (Hz), which is a period of repeating frequency response is described as a following mathematical formula 1.

$$P = \frac{1}{d} \qquad [ Mathematical formula 1 ]$$

According to the mathematical formula 1, the frequency response characteristic is controlled and amplitude of response is in direct proportion to the size of echo.

FIGS. 4A and 4B illustrate a diagram showing impulse response of an echo signal and frequency response of the impulse response when there is one negative echo pulse.

The frequency component corresponding to about 0-3 bark is decreased and the frequency component corresponding to about 3-6 bark is amplified when there is one negative echo pulse and the time delay value of the echo pulse is about 1 msec.

When the negative echo pulse is inserted into the audio signal, a sound quality change is occurred. A low tone is decreased and the tone of the audio signal becomes thin giving a cold feeling.

Even when there is the negative echo pulse, the period of the response change is controlled by controlling the time delay value.

In this case, the value of bark is changed according to the time delay value of the echo pulse.

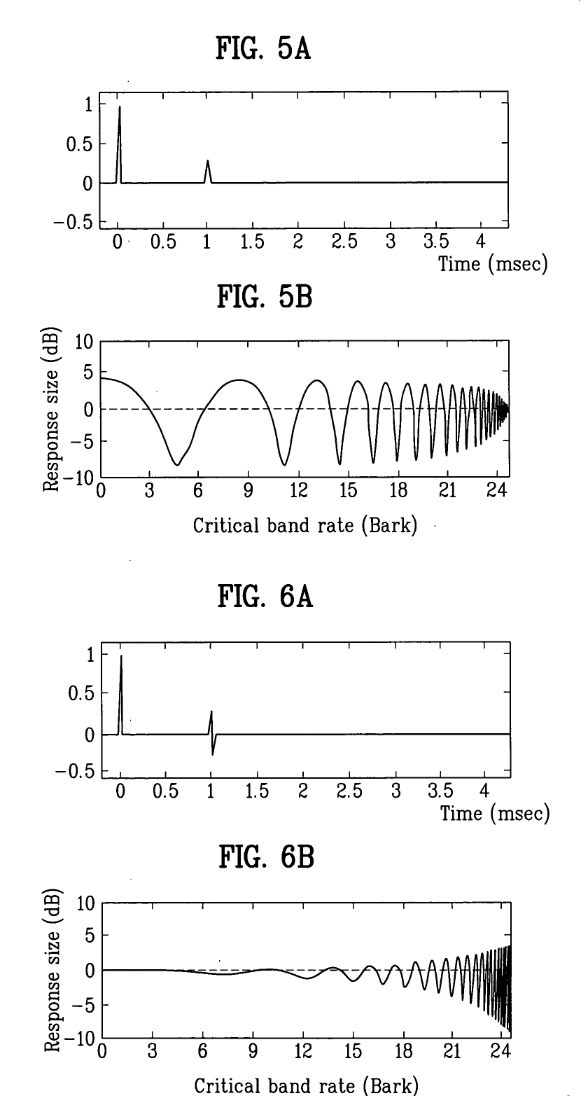

FIGS. 5A and 5B illustrate a diagram showing impulse response of an echo signal and frequency response of the impulse response when there are two positive echo pulses.

As illustrated in FIG. 5B, the response of the low frequency band is similar to the case of FIG. 3, however, different in that the size of the response change is decreased toward a direction of the high frequency band by associating two echo pulses.

FIGS. 6A and 6B illustrate a diagram showing impulse response of an echo signal and frequency response of the impulse response when there is one positive echo pulse and one negative echo pulse. As illustrated in FIG. 6B, although there is no response in the low frequency band, there is response in the high frequency band.

As mentioned above, the human ear is not able to perceive a high frequency response. Therefore, the response change of the high frequency is not recognized if the size of the pulse is not very large.

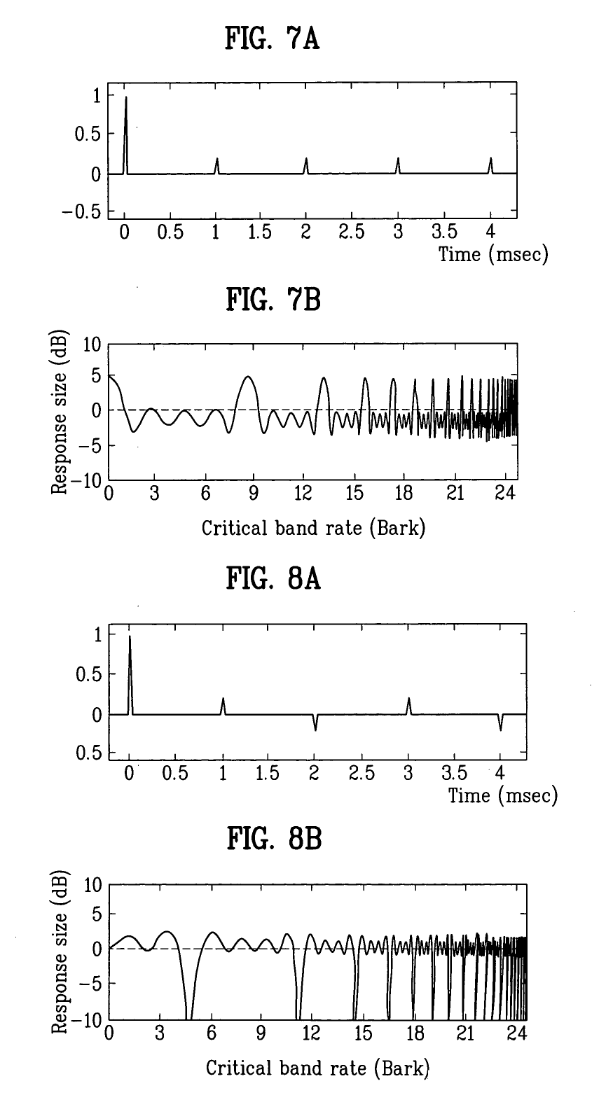

FIGS. 7A and 7B illustrate a diagram showing impulse response of an echo signal and frequency response of the impulse response when there are four positive echo pulses and FIGS. 8A and 8B illustrate a diagram showing impulse response of an echo signal and frequency response of the impulse response when there are two positive echo pulses and two negative echo pulses.

As illustrated in FIG. 7A, 7B, 8A and 8B, response in a form of amplifying or decreasing only frequency corresponding to a specific frequency by assembling a plurality of echo pulses. Except the case exampled in the drawing, reply change may be represented in various forms by utilizing various association of the echo pulse. In other words, the form of the frequency reply is changed according to the distance and the size of the echo pulse.

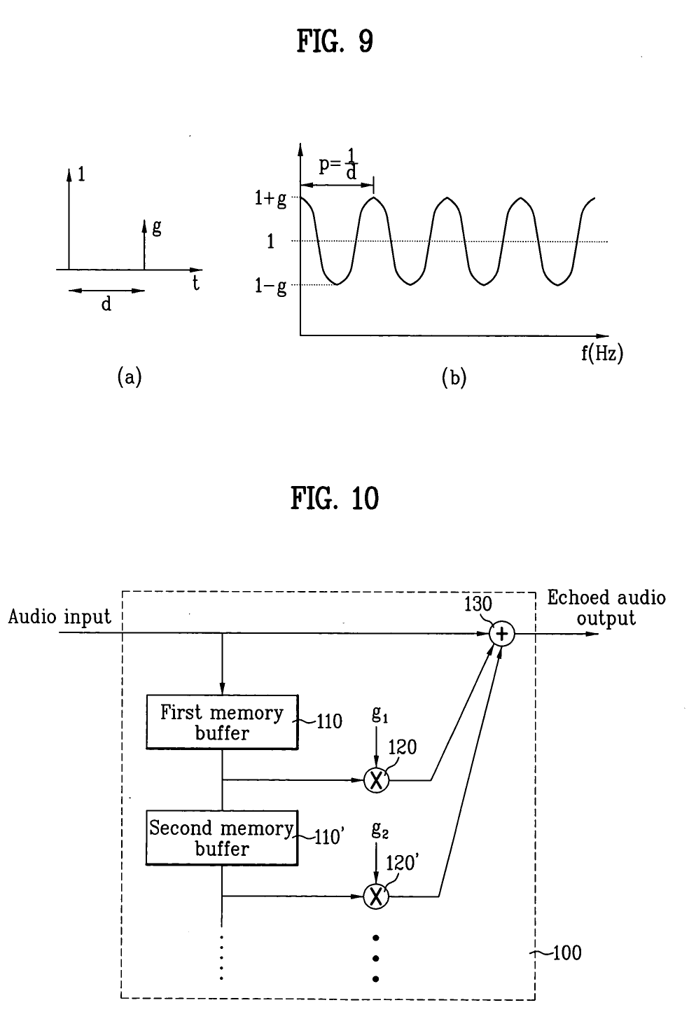

FIGS. 9A and 9B illustrate a diagram showing a change of frequency response according to a distance and a size of an original signal and an echo signal. As illustrated in FIGS. 9A and 9B, the repeated period of the frequency reply is the distance of the echo pulse, i.e., a reciprocal number of the time delay as described in the mathematical formula 1 and the size of the frequency replay is proportion to the gain value of the echo. Therefore, when there is a plurality of echo pulses, a complex frequency reply is represented by reciprocal action thereof.

As illustrated in FIGS. 9A and 9B, the time delay value (d) of the echo pulse and the repeated period (p) of the frequency reply are inverse proportion to each other. Thus, the frequency bands amplified or decreased according to the time delay value of the echo pulse are changed. The process of the echo insertion is described as a following mathematical formula 2.

$$y ( n ) = x ( n ) + {\sum }^{Number of Echo Pulses} {g}_{i} x ( n - di ) \qquad [ Mathematical Formula 2 ]$$

In this case, x(n): an input audio signal, y(n): an output audio signal, gᵢ: gain value (0-1) of i times echo pulse, and di: time delay value of i times echo pulse.

FIGS. 10 illustrates a tone converter in accordance with the present invention. The tone converter of the present invention includes at least one delayer, one multiplier, and one adder.

The delayer delays the input audio signal for a predetermined time so as to generate the echo pulse. The multiplier performs a role of multiplying the time delay value of the echo pulse outputted from the delayer corresponding to the multiplier by the gain value of the echo pulse. The adder adds the echo signal outputted from the multiplier and the input audio signal so as to output a tone converted audio signal.

In this case, a plurality of delayers and multipliers are provided and each delayer is correspondent to each multiplier. The delayer is a memory buffer for storing the audio signal in a size of the distance between the echo pulse and the input audio signal pulse.

According to the present invention, as illustrated in FIG. 10, two delayers such as the first memory buffer 110 and the second memory buffer 110′ are employed and each first multiplier 120 and the second multiplier 120′ are correspondent to each other at the first memory buffer 110 and the second memory buffer 110′.

The adder 130 adds the echo signal outputted from the first and second multipliers 120 and 120′ to the input signal so as to output the tone converted audio signal.

In this case, the first memory buffer 110 stores the audio signal in a size of the distance between the first echo pulse and the audio signal pulse, and the second memory buffer 110′ stores the audio signal in a size of the distance between the second echo pulse and the

If the echo pulse is increased, the number of the memory buffer and the multiplier is increased. The total volume of the memory buffer is a size for storing the time delay value of the original signal of the audio signal to the farthest echo pulse.

As a preferred embodiment, if about 5 msec of time is delayed for the audio signal sampled as 44.1 kHz, a volume of memory is needed for storing about 221 audio signal samples (44.1 kHz×5 msec=221).

In this case, if a digital signal is stored as a sample, it is possible to realize the present invention with a little amount of memory corresponding to the time delay length (less than the number msec) and the adder and multiplier in a size of the number of the echo pulse. Therefore, the amount of the operation may be disregarded.

If there are the delayer and a plurality of attenuated OP-AMP, the present invention may be realized in a case of an analog signal. As illustrated in FIG. 10, when the audio signal is inputted into the echo processor 100, the first memory buffer 110 delays the input audio signal for a predetermined time so as to generate the first echo pulse. Then, the first multiplier 120 multiplies time delay value of the first echo pulse outputted from the first memory buffer 110 and the gain value of the first echo pulse.

Meanwhile, the second memory buffer 110′ delays the audio signal outputted from the first memory buffer 110 for a predetermined time so as to generated the second echo pulse, and the second multiplier 120′ multiplies the time delay value of the second echo pulse outputted from the second memory buffer 110′ by the gain value of the second echo pulse. The adder 130 adds the echo signals outputted from the first and second multipliers 120 and 120′ to the input audio signal so as to generate the audio signal. As aforementioned, the tone converter and the tone converting method of the same have following effects.

The present invention simply and effectively converts the tone using the echo or the reverberation. The structure of the tone converter is very simple because the amount of operation is not very much. The tone is converted into various tones by using the number, gain, and the time delay of the echo pulse. The tone quality is improved by appropriately coordinating the number, gain, and the time delay of the echo pulse. Since the tone converter may be utilized as an audio player or an effecter of the amplifier, the present invention may be utilized as a post processor for improving the audio quality and the voice signal, the audio damaged by broadcast or a cable/radio communication.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A tone converter, comprising:
at least one delayer for generating an echo pulse by delaying an input audio signal for a predetermined time;
a multiplier for multiplying a time delay value of the echo pulse outputted from a corresponding delayer by a gain value; and
an adder for adding an echo signal outputted from the multiplier to the input audio signal so as to output a tone converted audio signal.

2. The tone converter of claim 1, wherein a plurality of delayers and multipliers are comprised, and each of the delayer is correspondent to each of the multiplier.

3. The tone converter of claim 1, wherein number of the delayer and the multiplier is determined according to number of the echo pulse.

4. The tone converter of claim 1, wherein the delayer is a memory buffer for storing an audio signal in a size of a distance between the echo pulse and the input audio signal pulse.

5. A tone converter, comprising:
a first delayer for generating a first echo pulse by delaying an input audio signal for a predetermined time;
a first multiplier for multiplying a time delay value of the first echo pulse outputted from the first delayer by a gain value of the first echo pulse;
a second delayer for generating a second echo pulse by delaying an audio signal outputted from the first delayer for a predetermined time;
a second multiplier for multiplying a time delay value of the first echo pulse outputted from the first delayer by a gain value of the first echo pulse; and
an adder for adding an echo signal outputted from the multiplier to the input audio signal so as to output tone converted audio signal.

6. The tone converter of claim 5, wherein the first multiplier and the second multiplier are arranged to be correspondent to the first delayer and the second delayer, relatively.

7. The tone converter of claim 5, wherein the first delayer is a memory buffer for storing the audio signal in a size between the first echo pulse and the input audio signal pulse and the second delayer is a memory buffer for storing the audio signal in a size between the second echo pulse and the first echo pulse.

8. An audio signal converting method of a tone converter comprising at least one delayer and multiplier, and an adder, the method comprising the steps of:
inputting the audio signal;
delaying the input audio signal for a predetermined time so as to generate the echo pulse;
multiplying a time delay value of the echo pulse by a gain value of the echo pulse; and
adding the multiplied echo signal and the input audio signal so as to output a tone converted audio signal.

9. The converting method of claim 8, wherein a repeated period of a frequency response of the echo signal is an inverse number of the time delay value of the echo pulse.

10. The converting method of claim 8, wherein a size of the frequency response of the echo signal is proportion to the gain value of the echo pulse.

11. The converting method of claim 8, wherein the tone converted audio signal is determined by a following mathematical formula.
$$y ( n ) = x ( n ) + {\sum }^{Number of Echo Pulses} {g}_{i} x ( n - di ) \qquad [ Mathematical Formula ]$$
Wherein, x(n): an input audio signal, y(n): an output audio signal, gᵢ: gain value (0-1) of i times echo pulse, and di: time delay value of i times echo pulse.
